(19) United States
(12) Patent Application Publication
(10) Pub. No.: US 2009/0155733 A1
(43) Pub. Date: Jun. 18, 2009

(54) METHOD OF FORMING ISO SPACE PATTERN

(75) Inventors: Kuo-Yao Cho, Taichung County (TW); Feng-Yi Chen, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 12/050,931

(22) Filed: Mar. 18, 2008

(30) Foreign Application Priority Data
Dec. 12, 2007 (TW) 96147475

(51) Int. Cl. G03F 7/26; G03F 7/40

(52) U.S. Cl. 430/324; 430/326

(57) ABSTRACT

A method of forming an iso space pattern is provided. In the method, a first material layer is provided, and then a second material layer and a patterned material layer are formed thereon. After that, a first patterned photoresist layer is formed on the patterned material layer to partially cover the patterned material layer and to partially expose the patterned material layer, and the second material layer is then partially removed by using the first patterned photoresist layer and the patterned material layer as a mask. Afterwards, the iso space pattern constituted by the etched second material layer is formed after the first patterned photoresist layer and the patterned material layer are removed. Due to twice photolithography and etching processes, it is likely to form the relatively narrow iso space pattern with use of existing photolithography equipments according to the method.

### CROSS-REFERENCE TO RELATED APPLICATION

This application claims the priority benefit of Taiwan application serial no. 96147475, filed on Dec. 12, 2007. The entirety the above-mentioned patent application is hereby incorporated by reference herein and made a part of specification.

### BACKGROUND OF THE INVENTION

1. Field of the Invention

The present invention is related to a method of forming an isolated space pattern by performing photolithography and etching processes twice. In the following description, the word “isolated” may be represented by an abbreviation, iso.

2. Description of Related Art

Conventional photolithography process is implemented by first coating a layer of a photosensitive material, such as photoresist material on a surface of a chip. Next, parallel light emitted from a light source is permitted to illuminate the photosensitive material layer after the light passes a photomask mainly made of glass, such that the photosensitive material layer is exposed. After the photosensitive material layer is developed, patterns on the photomask are completely transferred to the photosensitive material layer on the surface of the chip. In conventional exposure process, the wavelength of the light emitted from the light source poses an impact on the resolution of the development process. The shorter the wavelength is, the better the resolution is.

Thereby, a relatively narrow iso space pattern can be formed after an etching process is carried out.

In general, the wavelength of the light adopted in the conventional photolithography process ranges from 5600 Å to 6000 Å approximately. Hence, current demands for forming the relative narrow iso space pattern cannot be satisfied by the conventional photolithography process. As such, it is urgently required to form the relatively narrow iso space pattern by implementing the existing photolithography process.

### SUMMARY OF THE INVENTION

The present invention is directed to a method of forming an iso space pattern, so as to form a relatively narrow iso space pattern after an exposure to a light source having a normal wavelength and an implementation of a development process and an etching process. Thereby, the dimension of the iso space pattern is no longer restricted by the wavelength of the light in a photolithography process.

The present invention is further directed to a method of forming an iso space pattern. Through performing simple manufacturing processes and utilizing existing photolithography equipment, the method is capable of fabricating the iso space pattern beyond an extent to which a conventional photolithography process can reach.

The present invention provides a method of forming an iso space pattern. In the method, a first material layer is provided, and then a second material layer is formed on the first material layer. Next, a patterned material layer is formed on the second material layer. After that, a first patterned photoresist layer is formed on the patterned material layer to partially cover the patterned material layer and to partially expose the patterned material layer. Here, the first patterned photoresist layer has first openings each defined between two adjacent patterns of the first patterned photoresist layer and provided with a first lateral distance. Thereafter, by using the first patterned photoresist layer and the patterned material layer as a mask, the second material layer is partially removed so that the second material layer is patterned and has second openings each defined between two adjacent patterns of the second patterned material layer and provided with a second lateral distance being smaller than that of the first lateral distance. Afterwards, the first patterned photoresist layer and the patterned material layer are removed so that the iso space pattern is constituted by the patterned second material layer.

According to an embodiment of the present invention, the first patterned photoresist layer is made of positive-type photoresist.

The present invention further provides a method of forming an iso space pattern. First, a first material layer is provided. A second material layer having at least one first opening is then formed on the first material layer. The first opening exposes a portion of the first material layer. Next, a first patterned photoresist layer is formed on the second material layer, wherein patterns of the first patterned photoresist layer have a first density and cover a portion of the second material layer and a portion of the first material layer. Thereafter, the first material layer is patterned by using the first patterned photoresist layer and the second material layer as a mask so that the first material layer has at least one second opening such that the patterns of the first material layer is provided with a second density larger than the first density of the patterns of the first photoresist layer.

The present invention further provides a patterning method. In the method, a first material layer and a second material are sequentially formed on a substrate. Next, a first photoresist layer is formed on the second material layer. A first exposure region is then defined in the first photoresist layer, and the first exposure region corresponds to a first resolution. After that, a first opening is defined in the second material layer by means of the first exposure region. Thereafter, a second photoresist layer is formed on the first material layer, and a second exposure region is then defined in the second photoresist layer. Here, the second exposure region corresponds to a second resolution, and the second exposure region and the first exposure region are partially overlapped.

Next, a second opening is defined within the first material layer by using the second exposure region. The second opening is smaller than the first opening.

The present invention further provides a patterning method. In the method, a first material layer and a second material are sequentially formed on a substrate. Next, a first photoresist layer is formed on the second material layer. A first exposure region is then defined in the first photoresist layer, and the first exposure region corresponds to a resolution. After that, a first opening is defined in the second material layer by means of the first exposure region. Thereafter, a second photoresist layer is formed on the first material layer, and a second exposure region is then defined in the second photoresist layer. Here, the second exposure region corresponds to the same resolution, and the second exposure region and the first exposure region are partially overlapped.

Afterwards, a second opening is defined within the first material layer by using the second exposure region. The second opening is smaller than the first opening.

The photolithography and etching processes are performed twice in the present invention, so the relatively narrow iso space pattern is formed. Thereby, a dimension of the iso space pattern is no longer restricted by the wavelength of the light in the photolithography process. Moreover, the utilized light source during the exposure process can be, for example, I-line, krypton-fluoride (KrF) laser, and so on, evidencing the simplicity of the method proposed in the present invention.

In order to make the aforementioned and other objects, features and advantages of the present invention more comprehensible, several embodiments accompanied with figures are described in detail below.

### BRIEF DESCRIPTION OF THE DRAWINGS

FIG. 1A through 1G are cross-sectional flowcharts illustrating a process of forming an iso space pattern according to an embodiment of the present invention.

FIG. 2A through 2J are cross-sectional flowcharts illustrating a process of forming an iso space pattern according to another embodiment of the present invention.

FIG. 3A-1 through 3C-1 are top views illustrating a process of forming an iso space pattern according to still another embodiment of the present invention.

FIG. 3A-2 through 3C-2 are schematic cross-sectional views alone a sectional line a-a′ depicted in FIGS. 3A-1 through 3C-1.

### DESCRIPTION OF EMBODIMENTS

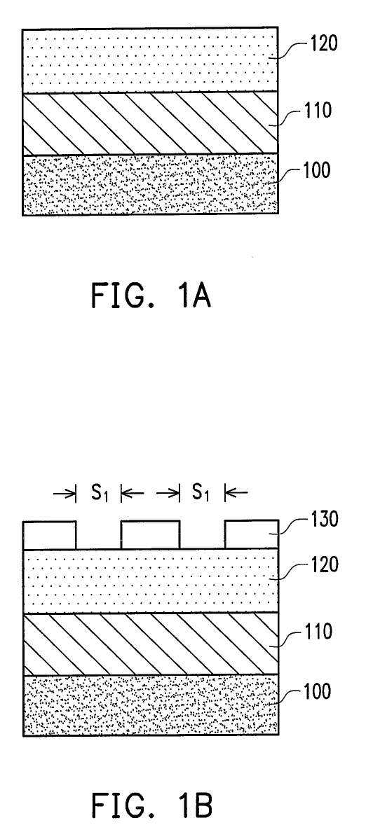

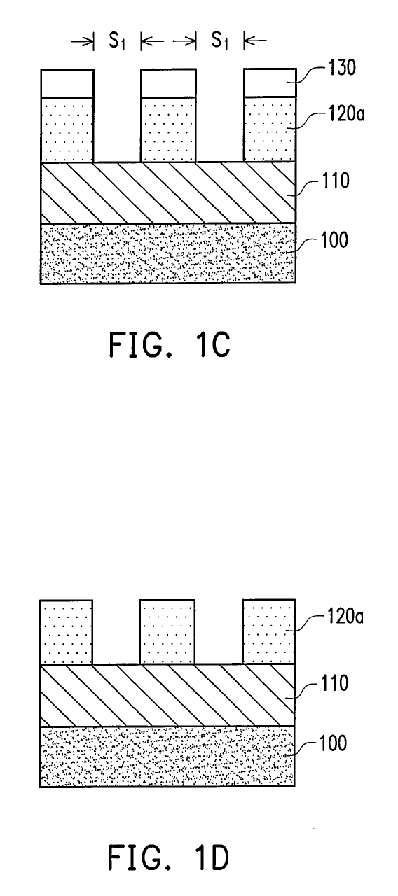

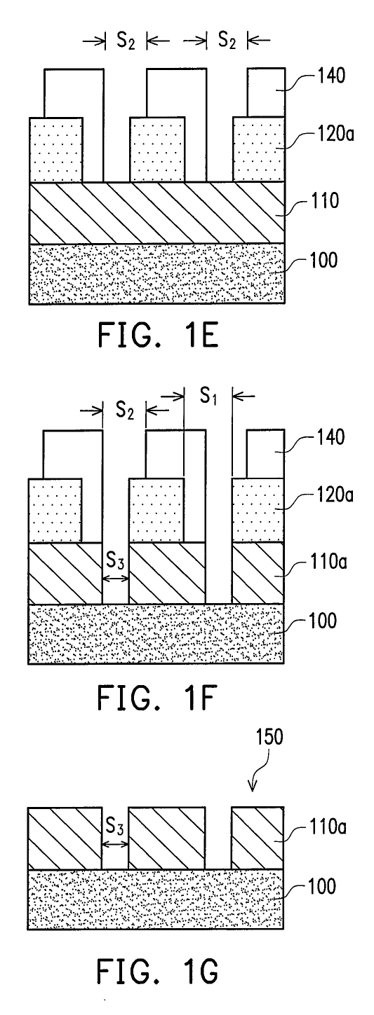

FIGS. 1A through 1G are cross-sectional flowcharts illustrating a process of forming an iso space pattern according to an embodiment of the present invention.

Referring to FIG. 1A, a first material layer 100 is first provided, and a second material layer 110 is formed on the first material layer 100. After that, a patterned material layer is formed on the second material layer 110. In the present embodiment, the method of forming the patterned material layer includes laminating a third material layer 120 on the second material layer 110, for example. Each of the material layers discussed hereinbefore can be made of silicon, silicon oxide, silicon nitride, or other materials based on actual demands.

After that, referring to FIG. 1B, a patterned photoresist layer 130 is formed on the third material layer 120. The patterned photoresist layer 130 has first openings defined therein and each opening is provided with a lateral distance S₁. Moreover, the patterned photoresist layer 130 is made of positive-type photoresist or negative-type photoresist, preferably is made of positive-type photoresist.

Thereafter, referring to FIG. 1C, the third material layer 120 is partially removed with use of the patterned photoresist layer 130 as a mask, so as to form a patterned material layer 120a. The patterned material layer 120a also has openings with the same dimension as that of the openings of the photoresist layer 130, namely distances S₁. Note that the photolithography process implemented during the formation of the patterned photoresist layer 130 reaches the maximum resolution which can be accomplished by the existing photolithography process according to the present embodiment.

Next, referring to FIG. 1D, the patterned photoresist layer 130 is removed by, for example, performing a dry stripping process with plasma.

Afterwards, referring to FIG. 1E, another patterned photoresist layer 140 is formed on the patterned material layer 120a. The patterned photoresist layer 140 covers a portion of the patterned material layer 120a and overlaps a portion of the second material layer 110. In addition, the patterned photoresist layer 140 has second openings each with a lateral distance S2 and is made of the positive-type photoresist or the negative-type photoresist. Moreover, the patterned photoresist layer 140 and the previously discussed patterned photoresist layer 130 are made of the same or different photoresist materials and/or have identical or different patterns. Note that the exposure light source employed in the photolithography process implemented during the formation of the patterned photoresist layer 140 reaches the maximum resolution which can be achieved by the existing photolithography process according to the present embodiment.

Thereafter, referring to FIG. 1F, an etching process is performed on the second material layer 110 with use of the patterned photoresist layer 140 and the patterned material layer 120a as the mask, so as to form a patterned second material layer 110a.

Next, referring to FIG. 1G, the patterned photoresist layer 140 and the patterned material layer 120a are removed for forming an iso space pattern 150 having third openings each with a lateral distance S₃ defined between two adjacent patterned second material layer 110a. Here, the iso space pattern 150 is constituted by the etched and patterned second material layer 110a. The patterned photoresist layer 140 and the patterned material layer 120a are removed by, for example, performing the dry stripping process with use of the plasma. It should be mentioned that the distance S₃ of the iso space pattern is smaller than the distance S₁ of the patterned material layer 120a and the distance S₂ of the patterned photoresist layer 140 respectively. That is to say, through implementing the photolithography and etching processes twice, the iso space pattern 150 with the relatively narrow distance S₃ is formed, bringing about a solution to a limitation posed on a dimension of the iso space pattern in the existing photolithography process.

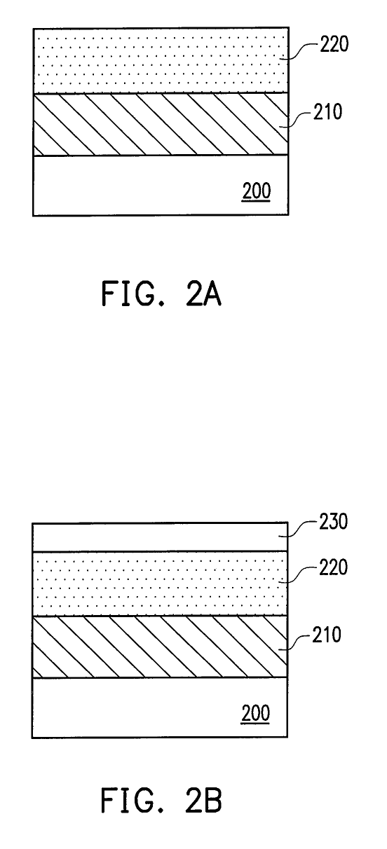

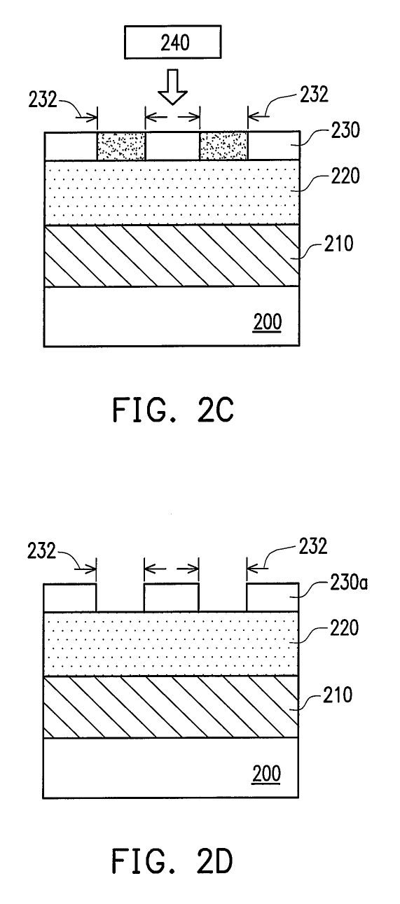

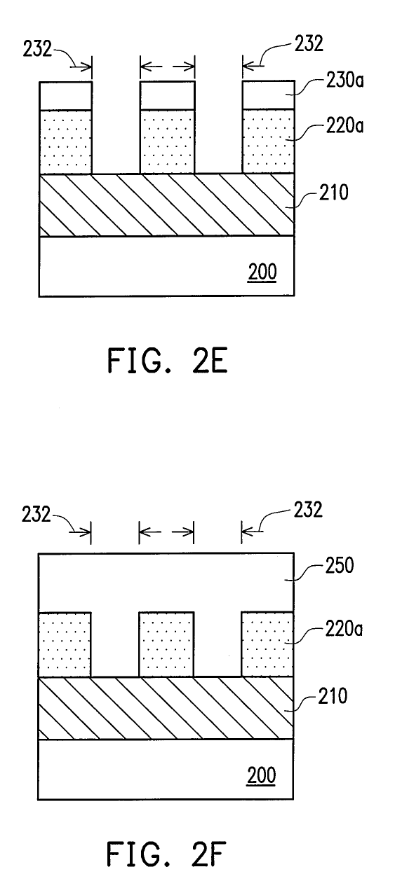

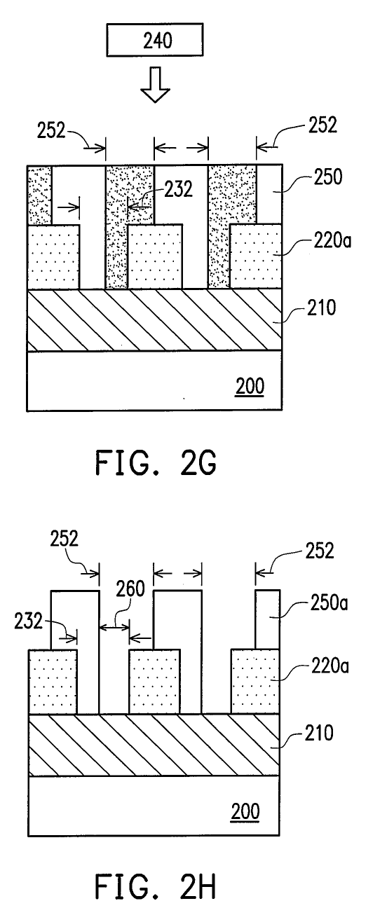

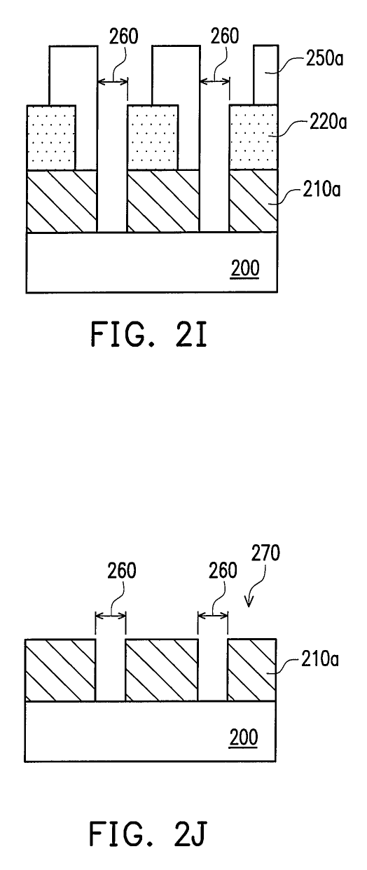

FIGS. 2A through 2J are cross-sectional flowcharts illustrating a process of forming an iso space pattern according to another embodiment of the present invention.

Referring to FIG. 2A, a first material layer 210 and a second material layer 220 are sequentially formed on a substrate 200. The first material layer 210 and the second material layer 220 can be made of silicon, silicon oxide, silicon nitride, or other materials including photoresist materials based on the actual demands.

Afterwards, referring to FIG. 2B, a first photoresist layer 230 is formed on the second material layer 220. The first photoresist layer 230 is made of the positive-type photoresist or the negative-type photoresist. The first photoresist layer 230 is, for example, made of photosensitive materials comprising resin, photosensitizers, and solvents. After several processes including a spin-coating process and a soft-baking process are carried out, the first photoresist layer 230 is formed on the second material layer 220. According to the present embodiment, the first photoresist layer 230 is made of the positive-type photoresist.

Next, referring to FIG. 2C, a photolithography machine 240 is employed for exposing first regions 232 of the first photoresist layer 230, so as to define first exposure regions corresponding to a first resolution. A dimension of the first regions 232 is obtained after an exposure process is performed by the photolithography machine 240.

Thereafter, referring to FIG. 2D, the first photoresist layer 230 is developed to partially expose the second material layer 220 underlying the first regions 232.

Afterwards, referring to FIG. 2E, the second material layer 220 is etched by using a first photoresist layer 230a as the mask, so as to construct first openings in the second material layer 220 and partially expose the first material layer 210 underlying the second material layer 220. The first openings correspond to the first regions 232.

Next, the first photoresist layer 230a is removed by, for example, performing the dry stripping process with use of the plasma.

As shown in FIG. 2F, a second photoresist layer 250 is then formed over the substrate 200. The second photoresist layer 250 is, for example, made of the photosensitive materials comprising resin, the photosensitizers, and the solvents. After several processes including the spin-coating process and the soft-baking process are carried out, the second photoresist layer 250 is formed over the substrate 200. The second photoresist layer 250 is made of the positive-type photoresist or the negative-type photoresist, for example. In addition, the second photoresist layer 250 and the first photoresist layer 230 include identical or different photoresist materials.

According to the present embodiment, the second photoresist layer 250 is made of the positive-type photoresist.

Thereafter, as indicated in FIG. 2G, the photolithography machine 240 is employed for exposing second regions 252 of the second photoresist layer 250, so as to define second exposure regions corresponding to a second resolution. The second resolution is either equal or unequal to the first resolution. In addition, the second regions 252 and the first regions 232 are partially overlapped. In the present embodiment, a dimension of the second regions 252 is identical to that of the first regions 232, while the two regions 232 and 252 can also be of different sizes.

After that, referring to FIG. 2H, the second photoresist layer 250 is developed to partially expose the first material layer 210 and the second material layer 220a underlying the second regions 252. Here, overlapping regions 260 between the first regions 232 and the second regions 252 have a dimension less than that of the first resolution or the second resolution.

Next, as illustrated in FIG. 2I, the first material layer 210 is etched by using the second patterned photoresist layer 250a and the second material layer 220a as the mask, so as to construct second openings in the first material layer 210. The second openings correspond to the overlapping regions 260.

With reference to FIG. 2J, the second patterned photoresist layer 250a and the second material layer 220a having the second openings are then removed to form an iso space pattern 270 constituted by the etched first material layer 210a. The second patterned photoresist layer 250 and the remaining second material layer 220a are removed by, for example, performing the dry stripping process with use of the plasma.

The iso space pattern 270 can be applied to various manufacturing processes.

For instance, the substrate 200 can be etched with use of the iso space pattern 270 as the mask, so as to form a plurality of deep trenches (not shown) applicable to deep trench capacitors. In addition, two material layers are taken to exemplify the subject invention according to the present embodiment, while multi-layered materials can also be adopted in other embodiments. Hence, based on the actual demands, the photolithography and etching processes can be carried out for twice or more.

FIGS. 3A-1 through 3C-1 are top views illustrating a process of forming an iso space pattern according to still another embodiment of the present invention.

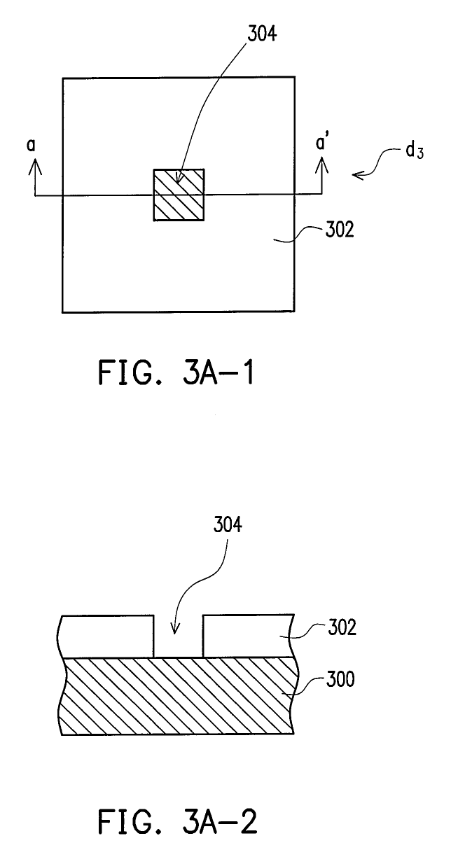

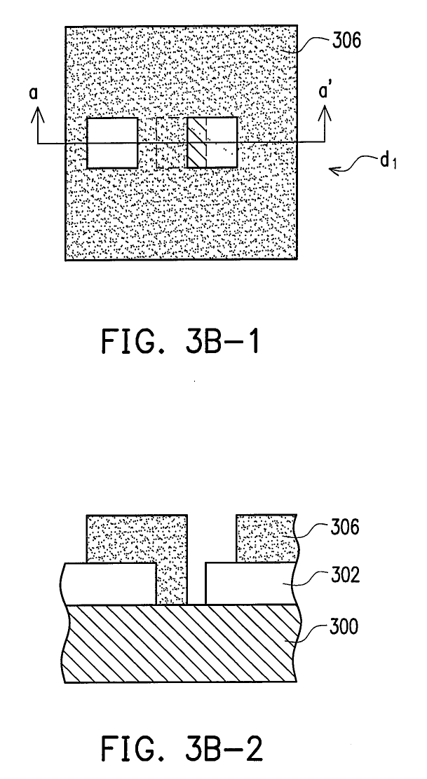

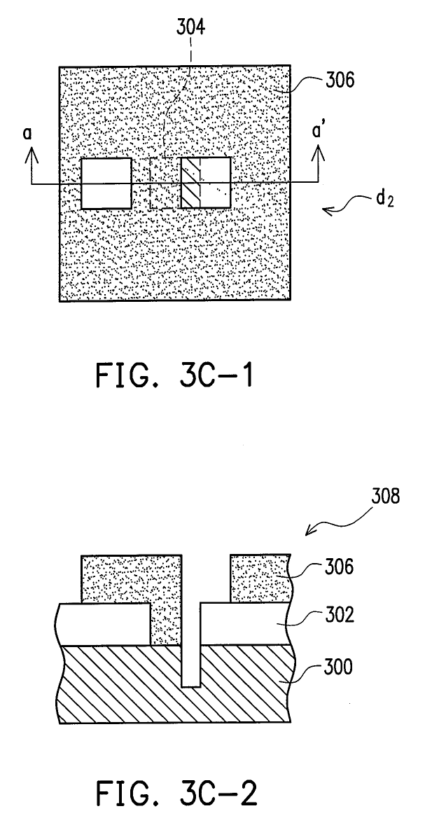

FIGS. 3A-2 through 3C-2 are schematic cross-sectional views alone a sectional line a-a′ depicted in FIGS. 3A-1 through 3C-1.

First, referring to FIGS. 3A-1 and 3A-2, a first material layer 300 is provided.

Next, a second material layer 302 having an opening 304 is formed on the first material layer 300. The opening 304 exposes a portion of the first material layer 300. For instance, the method of forming the opening 304 within the second material layer 302 includes forming a patterned photoresist layer (not shown) on the second material layer 302. Here, patterns of the patterned photoresist layer has a density d₃.

Next, a portion of the second material layer 302 is removed by using the patterned photoresist layer as an etching mask to form the opening 304.

After that, referring to FIGS. 3B-1 and 3B-2, a first patterned photoresist layer 306 is formed on the second material layer 302, and patterns of the first patterned photoresist layer 306 have a density d₁. The first patterned photoresist layer 306 covers a portion of the second material layer 302 and a portion of the first material layer 300. Note that the density d₁ is identical to the density d₃ of the patterned photoresist layer used for forming the opening 304 of the second material layer 302.

Thereafter, as indicated in FIGS. 3C-1 and 3C-2, an iso space pattern 308 is defined on the first material layer 300 by means of the opening 304, and patterns of the iso space pattern 308 have a density d₂. It should be mentioned that the density d₃ of the patterned photoresist layer used for forming the opening 304 of the second material layer 302 and the density d₁ of the first patterned photoresist layer 306 are lower than the density d₂ of the iso space pattern 308. In other words, through the implementation of the photolithography and etching processes for twice, the iso space pattern 308 having the density d₂ greater than the density d₃ of the patterned photoresist layer can be formed.

To sum up, the patterned photoresist layer and the material layer formed by performing the first photolithography and etching process are used as the mask for carrying out the second photolithography and etching process according to the present invention. Through the implementation of the photolithography and etching processes for twice, the relatively narrow iso space pattern can be formed in comparison with the iso space patterned constructed in accordance with the pertinent art. Moreover, in the present invention, the photolithography process can be performed with use of the existing I-line system or the KrF laser equipment in no need of employing other specialized machines. Thereby, the conventional issue regarding the limitation posed on the dimension of the iso space pattern due to the wavelength of the light is resolved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming an iso space pattern, the method comprising:
providing a first material layer;
forming a second material layer on the first material layer;
forming a patterned material layer on the second material layer;
forming a first patterned photoresist layer on the patterned material layer to partially cover the patterned material layer and to partially expose the patterned material layer, the first patterned photoresist layer having first openings each defined between two adjacent patterns of the first patterned photoresist layer and provided with a first lateral distance;
partially removing the second material layer by using the first patterned photoresist layer and the patterned material layer as a mask so that the second material layer is patterned and has second openings each defined between two adjacent patterns of the second patterned material layer and provided with a second lateral distance being smaller than that of the first lateral distance; and
removing the first patterned photoresist layer and the patterned material layer so that the iso space pattern is constituted by the patterned second material layer.

2. The method as claimed in claim 1, wherein the first patterned photoresist layer is made of positive-type photoresist.

3. A method of forming an iso space pattern, comprising:
providing a first material layer;
forming a second material layer on the first material layer, wherein the second material layer has at least one first opening exposing a portion of the first material layer;
forming a first patterned photoresist layer on the second material layer, wherein patterns of the first patterned photoresist layer have a first density and cover a portion of the second material layer and a portion of the first material layer; and
patterning the first material layer by using the first patterned photoresist layer and the second material layer as a mask so that the first material layer has at least one second opening such that the patterns of the first material layer is provided with a second density larger than the first density of the patterns of the first photoresist layer.

4. A patterning method, comprising:
forming a first material layer and a second material layer on a substrate in sequence;
forming a first photoresist layer on the second material layer;
defining a first exposure region in the first photoresist layer, the first exposure region corresponding to a first resolution;
defining a first opening in the second material layer by using the first exposure region;
forming a second photoresist layer on the first material layer;
defining a second exposure region in the second photoresist layer, the second exposure region corresponding to a second resolution, wherein the second exposure region and the first exposure region are partially overlapped; and
defining a second opening within the first material layer by using the second exposure region, wherein the second opening is smaller than the first opening.

5. A patterning method, comprising:
forming a first material layer and a second material layer on a substrate in sequence;
forming a first photoresist layer on the second material layer;
defining a first exposure region in the first photoresist layer, the first exposure region corresponding to a resolution;
defining a first opening in the second material layer by using the first exposure region;
forming a second photoresist layer on the first material layer;
defining a second exposure region corresponding to the resolution in the second photoresist layer, wherein the second exposure region and the first exposure region are partially overlapped; and
defining a second opening in the first material layer by using the second exposure region, wherein the second opening is smaller than the first opening.
